(19) United States
(12) Patent Application Publication
(10) Pub. No.: US 2026/0166871 A1
(43) Pub. Date: Jun. 18, 2026

(54) LAMINATING APPARATUS, LAMINATING METHOD USING SAME, AND ELECTRONIC DEVICE

(71) Applicant: Samsung Display Co., Ltd., Yongin-si (KR)

(72) Inventors: WOO-HYUN KWON, Yongin-si (KR); SAN PARK, Yongin-si (KR); YANGHAN SON, Yongin-si (KR); SOHYUN KIM, Yongin-si (KR); WU HYEON JUNG, Yongin-si (KR)

(21) Appl. No.: 19/413,945

(22) Filed: Dec. 9, 2025

(30) Foreign Application Priority Data
Dec. 13, 2024 (KR) 10-2024-0186271

(51) Int. Cl. B32B 37/10; B32B 37/06; B32B 38/00; H05K 5/03

(52) U.S. Cl. CPC B32B 37/10; B32B 37/06; B32B 38/1875; H05K 5/03; B32B 2457/20

(57) ABSTRACT

A laminating apparatus and a laminating method utilizing the laminating apparatus are disclosed. The laminating apparatus may include a first jig configured or arranged such that a cover window having a curvature in at least an area is seated on the first jig, a second jig arranged opposite to the first jig, and a pressing pad arranged on the second jig, configured such that a panel member to which a secondary film is attached is seated on the pressing pad, and having a pressing surface conforming to the shape of the cover window.

### CROSS-REFERENCE TO RELATED APPLICATION

The present application claims priority to and the benefit of Korean Patent Application No. 10-2024-0186271, filed on Dec. 13, 2024, in the Korean Intellectual Property Office, the entire disclosure of which is incorporated herein by reference.

### BACKGROUND

### 1. Field

One or more embodiments of the present disclosure relate to a laminating apparatus and a laminating method utilizing the laminating apparatus.

One or more embodiments of the present disclosure relate to an electronic device.

### 2. Description of the Related Art

Electronic devices, such as smart phones, mobile phones, and/or multimedia players, utilize or include a display device, such as a light-emitting display and/or a liquid crystal display (LCD). The display device may often be one of the most prominent and externally visible components of the electronic device, and thus may play a key role in both the functionality and aesthetic design of the device.

A display device includes a display panel and a protective window. The window serves to protect the display panel from external impact and environmental factors. These two components may be bonded together using an adhesive layer. A laminating apparatus may be employed to perform this bonding process with precision and reliability.

The foregoing description of related art is provided for the purpose of understanding the context of the present disclosure and is not to be construed as an admission that such information constitutes prior art known to those of ordinary skill in the art at the time of filing.

### SUMMARY

One or more aspects of embodiments of the present disclosure are directed toward a laminating apparatus capable of laminating a window and a panel and a laminating method using the laminating apparatus.

Additional aspects of embodiments will be set forth in part in the description which follows and, in part, will be apparent from the description or may be learned by practice of the presented embodiments of the disclosure.

One or more embodiments of the present disclosure provide a laminating apparatus including: a first jig configured or arranged such that a cover window having a curvature in at least an area is seated on the first jig; a second jig arranged opposite to the first jig; and a pressing pad arranged on the second jig, configured or arranged such that a panel member to which a secondary film is attached is seated on the pressing pad, and having a pressing surface conforming to the shape of the cover window. For example, the laminating apparatus may include the first jig configured to support a cover window having a curvature in at least a portion of its surface. The second jig may be positioned opposite to the first jig, and the pressing pad may be arranged on the second jig. The pressing pad may be designed to receive the panel member with the attached secondary film and may include the pressing surface that conforms to the shape of the curved cover window.

In one or more embodiments, the pressing pad may include: a pad core coupled to the second jig; and a pad cover covering the pad core and including a resilient material.

In one or more embodiments, the pad cover may have a hardness of a selected (e.g., set or predetermined) value or greater.

In one or more embodiments, the pad core may include a support protrusion protruding toward the pad cover.

In one or more embodiments, the laminating apparatus may further include a heater including a heating element arranged to generate heat while at least a portion of the heating element is in contact with the pressing pad.

In one or more embodiments, the heating element may be arranged between the second jig and the pressing pad.

In one or more embodiments, the pressing pad may include a pad core arranged to be coupled to the second jig, and the heating element may be arranged in the pad core.

In one or more embodiments, the laminating apparatus may further include a driver arranged to linearly move at least one selected from the first jig and the second jig.

In one or more embodiments, the second jig may include: a lifting pad connected to the driver and expandable to lift the pressing pad; and a lifting guide arranged to guide the direction of deformation of the lifting pad.

In one or more embodiments, the laminating apparatus may further include a film holder arranged adjacent to the second jig and configured or arranged to apply tension to the secondary film, wherein the panel member is configured to receive a tensile force transmitted through the secondary film by the film holder, such that a portion of the panel member is deformed to conform to a curved portion of the pressing surface.

In one or more embodiments, at least one of the first jig or the second jig may be to move such that the panel member and the cover window contact each other, and the pressing pad may be to press the panel member and the cover window.

One or more embodiments of the present disclosure provide a laminating method including: seating a cover window on a first jig; seating a panel member, to which a secondary film is attached, on a pressing pad arranged on a second jig; preforming the panel member by applying a tensile force to the secondary film; and pressing and laminating the panel member and the cover window.

In one or more embodiments, the laminating (e.g., the laminating of the panel member and the cover window) may include: placing the panel member and the cover window adjacent to each other by moving at least one of the first jig or the second jig; and attaching the panel member and the cover window to each other by pressing the panel member and the cover window.

In one or more embodiments, the cover window may have a curvature in at least an area, and the pressing pad may be to support the panel member to which the secondary film is attached and have a pressing surface conforming to the shape of the cover window.

In one or more embodiments, in the preforming (e.g., in the preforming of the panel member), the tensile force may be applied to the panel member supported on the pressing pad such that the panel member is deformed to contact a curved portion of the pressing surface.

In one or more embodiments, in the preforming (e.g., in the preforming of the panel member), wherein if (e.g., when) the tensile force is applied to the secondary film, the tensile force may be transferred to a first area of the panel member, and the pressing pad may be to support the panel member such that the tensile force is distributed to a second area adjacent to the first area.

In one or more embodiments, the laminating (e.g., the laminating of the panel member and the cover window) may include pressing the panel member supported on the pressing pad to be deformed to conform to the shape of the cover window.

In one or more embodiments, the pressing pad may include: a pad core coupled to the second jig; and a pad cover covering the pad core and including a resilient material, and in the laminating (e.g., in the laminating of the panel member and the cover window), the pad cover may be resiliently deformed to distribute pressure applied to the panel member.

In one or more embodiments, the laminating method may further include generating heat and transferring the heat to the panel member by a heating element in contact with the pressing pad.

In one or more embodiments, the preforming (e.g., the preforming of the panel member) and the laminating (e.g., the laminating of the panel member and the cover window) may be performed at substantially the same time.

One or more embodiments of the present disclosure provide an electronic device including: a controller to generate a scan input signal; a power device to generate a scan input voltage; and a display device including a display panel and a cover window covering the display panel, wherein in the display device, the cover window has a curvature in at least an area, and the display panel deformed to conform to the shape of the cover window is bonded to the cover window.

In one or more embodiments, the electronic device may be a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, and/or a head-mounted display (HMD).

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a conceptual view illustrating a laminating apparatus according to one or more embodiments of the present disclosure;

FIG. 2 is a conceptual view illustrating a pressing pad, and a panel member and a cover window arranged on the pressing pad;

FIG. 3 is a view illustrating an example of one or more components of the laminating apparatus of FIG. 1;

FIGS. 4 and 5 are views illustrating another example of one or more components of the laminating apparatus of FIG. 1;

FIG. 6 is a conceptual view illustrating a state in which the laminating apparatus of FIG. 1 preforms a panel member;

FIG. 7 is a conceptual view illustrating a state in which the laminating apparatus of FIG. 1 laminates a panel member and a cover window;

FIGS. 8 and 9 are cross-sectional views illustrating a process of deforming a panel member and a cover window;

FIG. 10 is a conceptual view illustrating a display device fabricated by the laminating apparatus of FIG. 1; and

FIG. 11 is a cross-sectional view illustrating portions of the display panel as illustrated in FIG. 10.

### DETAILED DESCRIPTION

The subject matter of the present disclosure may have one or more suitable modifications and one or more suitable embodiments, and thus certain embodiments will be shown in the drawings and described in more detail in the detailed description. The aspects and features of embodiments of the present disclosure and how to accomplish them will be apparent with reference to the following detailed description together with the accompanying drawings. However, the present disclosure is not limited to the embodiments as disclosed herein, but may be implemented in one or more suitable forms.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

As used herein, the term “and/or” includes any and all combinations of one or more of the associated listed items. For example, “A and/or B” indicates cases where it is A, or B, or both (e.g., simultaneously) A and B.

Throughout the present disclosure, the expression “at least one of a, b, or c” indicates only a, only b, only c, both (e.g., simultaneously) a and b, both (e.g., simultaneously) a and c, both (e.g., simultaneously) b and c, all of a, b, and c, or variations thereof.

The terms, such as “first,” “second,” and/or the like, may be used to describe one or more suitable elements, but these elements should not be limited by the terms. These terms are only used to distinguish one element, component, region, layer, or portion from another element, component, region, layer, or portion. For example, without departing from the scope of the present disclosure, a first element, a first component, a first region, a first layer, or a first portion may be referred to as a second element, a second component, a second region, a second layer, or a second portion, and similarly, the second element, the second component, the second region, the second layer, or the second portion may be referred to as the first element, the first component, the first region, the first layer, or the first portion.

As utilized herein, the singular forms “a,” “an,” and “the” are intended to include the plural forms as well, unless the context clearly indicates otherwise.

The terms, such as “include,” “including,” “have,” or “having,” are intended to imply the presence of a feature or a component as described in the present disclosure and do not preclude the possibility that one or more other features or components may be added. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

If (e.g., when) a portion, such as a unit, a region, or a component, is referred to as being above or on another portion, the portion may be directly above or on the other portion or an intervening portion, such as a unit, a region, or a component, may also be present between the two portions.

The terms, such as “connect” or “couple,” do not necessarily refer to a direct and/or fixed connection or coupling of two members, unless the context clearly indicates otherwise, and do not exclude the presence of other members provided between the two members. For example, it will be understood that if (e.g., when) an element or a layer is referred to as being “on”, “connected to”, or “coupled to” another element or layer, it may be directly on, directly connected to, or directly coupled to the other element or layer, or intervening third elements or layers may be present therebetween. In contrast, if (e.g., when) an element or a layer is referred to as being “directly on”, “directly conncected to”, or “directly coupled to” another element or layer, there are no intervening elements or layers present therebetween.

In the accompanying drawings, components may be exaggerated or reduced in size for ease of explanation. For example, the sizes and thicknesses of the respective components as illustrated in the drawings may be arbitrary for ease of explanation, and therefore embodiments of the present disclosure are not necessarily limited thereto.

Hereinafter, one or more embodiments of the present disclosure will be described in more detail with reference to the accompanying drawings, in which substantially identical or corresponding components are designated by the same reference numerals and repeated descriptions thereof may not be provided.

Hereinafter, a first direction and a second direction crossing the first direction are defined as substantially horizontal directions, and a third direction is defined as a vertical direction. In one or more embodiments of the present disclosure, the first direction may correspond to a width direction of a panel member, the second direction may correspond to a longitudinal direction of the panel member, and the third direction may correspond to a height direction of the panel member.

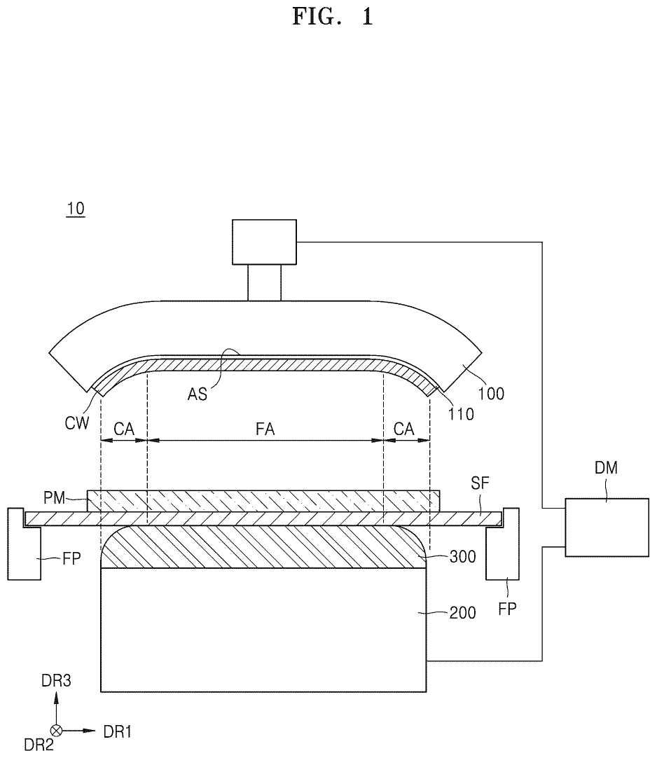

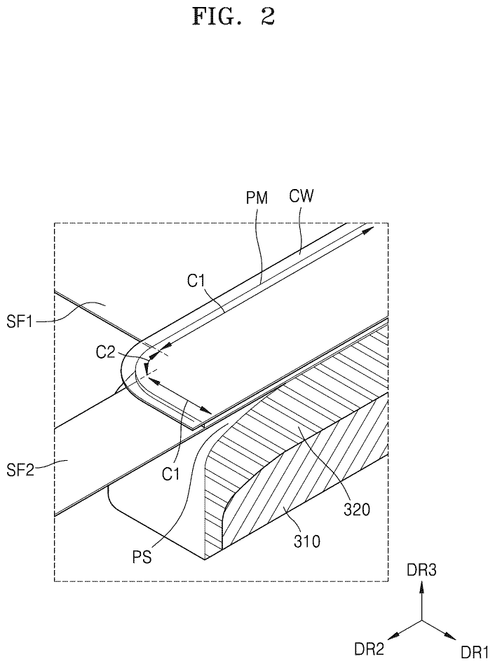

FIG. 1 is a conceptual view illustrating a laminating apparatus 10 according to one or more embodiments of the present disclosure, and FIG. 2 illustrates a pressing pad 300 as illustrated in FIG. 1 and a panel member PM and a cover window CW arranged on the pressing pad 300.

Referring to FIGS. 1 and 2, the cover window CW and the panel member PM may be seated on the laminating apparatus 10. In one or more embodiments, the panel member PM may be seated on the laminating apparatus 10 while attached to a secondary film SF. In the laminating apparatus 10, the cover window CW and the panel member PM may be laminated, thereby fabricating a display device.

The cover window CW may be formed or arranged to have a curved portion. For example, in the cover window CW, a central area may be flat (e.g., substantially flat), and edge areas extending from the central area may have a curvature. In another example, the cover window CW may be formed or arranged such that the entire area is curved. Furthermore, the curved areas of the cover window CW may have a constant curvature (e.g., a substantially constant curvature), or the curvature may vary.

For ease of description, the following description will focus on an embodiment in which the cover window CW is flat (e.g., substantially flat) at the center and curved at the opposite ends, as illustrated in FIG. 1.

The panel member PM may be a member to which the cover window CW is attached.

For example, the panel member PM may be a touch screen panel (TSP), a display panel, or a (e.g., any suitable) combination thereof utilized in a display device. In another example, the panel member PM may be a touch device. However, this is not intended to be limiting, and the panel member PM may be interpreted in the broadest sense herein. For example, the panel member PM may be understood to include a plate-shaped member (e.g., a substantially plate-shaped member).

The structure and functionality of the panel member PM will be described in more detail herein.

The panel member PM may be deformed by external forces. The panel member PM may be preformed under a tensile force prior to being attached to the cover window CW. The preformed panel member PM may be bonded to the cover window CW by a compressive force between a first jig 100 and a second jig 200. At this time, one or more areas of the panel member PM may be deformed to bend to conform to the shape of the cover window CW.

The secondary film SF may be attached to the panel member PM. The secondary film SF may be arranged in the laminating apparatus 10 while attached to one surface of the panel member PM and may be to guide the deformation of the panel member PM.

At least one side of the secondary film SF may be coupled to a film holder FP. In one or more embodiments, the film holder FP may have any suitable part or structure, such as a clamp, a holder, and/or the like, capable of supporting the secondary film SF.

The film holder FP may be to grip the secondary film SF to fix the position of the secondary film SF. In another example, the film holder FP may be to move the secondary film SF in at least one direction while gripping the secondary film SF. If (e.g., when) the position of the secondary film SF is fixed, the secondary film SF may be tensioned by the film holder FP. For example, the film holder FP may be to move with the secondary film SF or may be to apply the tensile force to the secondary film SF which is fixed in position.

In one or more embodiments, a first film SF1 and a second film SF2 may be attached to the panel member PM as illustrated in FIG. 2. The first film SF1 may extend from the panel member PM in a first direction DR1, and the second film SF2 may extend from the panel member PM in a second direction DR2. Hereinafter, an area of the panel member PM to which the first film SF1 and the second film SF2 are attached may be defined as a first area C1, and the remaining area may be defined as a second area C2.

The laminating apparatus 10 may include the first jig 100, the second jig 200, a driver DM, and the pressing pad 300.

The cover window CW may be seated on the first jig 100. A seating surface AS of the first jig 100 on which the cover window CW is seated may be formed or arranged to be recessed into one side of the first jig 100. The seating surface AS of the first jig 100 may be arranged such that portions are curved to conform to the shape of the cover window CW. For example, the seating surface AS of the first jig 100 may be arranged such that the central portion is flat (e.g., substantially flat) and the opposite ends are curved to conform to the cover window CW.

The first jig 100 may include a window holder 110. The window holder 110 may contact the cover window CW to fix the position of the cover window CW. The window holder 110 may prevent the cover window CW seated on the first jig 100 from being dislodged from the first jig 100 (or reduce a degree to or occurrence of which the cover window CW seated on the first jig 100 is dislodged from the first jig 100).

The manner in which the window holder 110 fixes the position of the cover window CW is not limited. For example, the window holder 110 may be provided as an adhesive material and may be applied to the seating surface of the first jig 100, as illustrated in FIG. 1, thereby allowing the cover window CW to be bonded to the first jig 100. In another example, the window holder 110 may be connected to a suction pump which is to draw air to hold the cover window CW by suction. In another example, the window holder 110 may have a separate frame, a separate clamp, a separate holder, and/or the like to mechanically fix the cover window CW.

The second jig 200 may be arranged opposite to the first jig 100. The pressing pad 300 to be described in more detail herein may be coupled to the second jig 200, and the panel member PM may be supported on the pressing pad 300. Thus, the first jig 100 and the second jig 200 may be spaced and/or apart (e.g., spaced apart or separated) from each other, but may be arranged such that the panel member PM and the cover window CW are opposite to each other.

For ease of description, the following description will focus on an embodiment in which the first jig 100 is arranged at an upper position and the second jig 200 is arranged below the first jig 100, as illustrated in FIG. 1. However, embodiments of the present disclosure are not limited thereto, and the first jig 100 may be arranged at a lower position and the second jig 200 may be arranged above the first jig 100. The first jig 100 and the second jig 200 may also be horizontally spaced and/or apart (e.g., spaced apart or separated) from each other.

The driver DM may be to move at least one selected from the first jig 100 and the second jig 200. The driver DM may be connected to at least one selected from the first jig 100 and the second jig 200 to drive the at least one selected from the first jig 100 and the second jig 200. The first jig 100 and the second jig 200 may be moved relative to each other by the driver DM, as a result of which the cover window CW and the panel member PM may be laminated.

For example, the driver DM may have a cylinder that is pneumatically or hydraulically operated to move the first jig 100 or the second jig 200. In another example, the driver DM may include a motor which is operated by electrical energy to move the first jig 100 or the second jig 200. For example, the manner in which the driver DM moves the first jig 100 and the second jig 200 is not limited.

The pressing pad 300 may be arranged on the second jig 200. The pressing pad 300 may be to support the panel member PM which is seated on the second jig 200. On the pressing pad 300, the panel member PM may be preformed under a tensile force. Furthermore, the pressing pad 300 may be to press the panel member PM and the cover window CW in response to the linear movement of the first jig 100 and/or the second jig 200. As a result, the panel member PM and the cover window CW may be laminated.

The pressing pad 300 may be formed or arranged to conform to the shape of the cover window CW. If (e.g., when) one surface of the pressing pad 300 on which the panel member PM is arranged is defined as a pressing surface PS, the pressing surface PS may have a curvature to conform to the shape of the cover window CW. For example, the pressing surface PS may have a flat area FA and curved areas CA to conform to the cover window CW.

For example, the panel member PM arranged on the pressing pad 300 may be deformed and preformed by an external force prior to being coupled to the cover window CW. If (e.g., when) an external force, for example, a tensile force, is applied to the panel member PM, the panel member PM supported on the pressing pad 300 may be deformed to conform to the pressing surface PS. Because the pressing surface PS of the pressing pad 300 is arranged to conform to the shape of the cover window CW, the panel member PM may be preformed to conform to the shape of the cover window CW.

If (e.g., when) a tensile force is applied to the secondary film SF attached to the panel member PM to preform, the tensile force may be directly transferred to the first area C1 of the panel member PM. At this time, if (e.g., when) a compressive stress is concentrated on the second area C2 of the panel member PM, buckling and/or the like may occur, thereby degrading the quality of the panel member PM.

Because the panel member PM is subjected to a tensile force while supported on the pressing pad 300, the tensile force may also be distributed to the second area C2 of the panel member PM. Accordingly, the laminating apparatus 10 may uniformly (e.g., substantially uniformly) preform the entire area of the panel member PM, thereby preventing quality degradation (or reducing a degree or occurrence of quality degradation) due to buckling and/or the like.

The pressing pad 300 may include a pad core 310 and a pad cover 320.

The pad core 310 may be coupled to the second jig 200 and may form the base of the pressing pad 300. The pad core 310 may be formed or composed of one or more suitable materials, such as metal, ceramic, and/or the like, but may maintain the shape during operation of the laminating apparatus 10. The pad core 310 may be to apply pressure to the panel member PM in conjunction with the first jig 100.

The pad cover 320 may cover the pad core 310. The pad cover 320 may be provided to wrap around the pad core 310 and may contact the panel member PM.

The pad cover 320 may be formed or composed of a resilient material. For example, the pad cover 320 may include silicone, rubber, and/or any other suitable deformable material. If (e.g., when) the pad core 310 applies a pressure to the panel member PM in conjunction with the first jig 100, the pad cover 320 may prevent direct impact (or reduce a degree or occurrence of direct impact) on the panel member PM, thereby protecting the panel member PM.

In one or more embodiments, the pad cover 320 may have a hardness equal to or greater than a reference value. Because the first jig 100 and the second jig 200 are coupled to press the cover window CW and the panel member PM as described in one or more embodiments, the pad cover 320 may act or serve as a buffer, but the shape of the pad cover 320 may change. For example, areas corresponding to the curved areas CA may expand outwards, thereby having a different curvature than the cover window CW. Accordingly, the pad cover 320 may have a hardness equal to or greater than the reference value to effectively or suitably act or serve as a buffer while maintaining the shape substantially conforming to the cover window CW.

For example, the pad cover 320 may include silicone having a Shore hardness of A40 or higher. The hardness of the pad cover 320 is not limited thereto, but may be selected suitably depending on the material of the panel member PM, the curvature of the curved areas CA, and/or the like.

In the following, one or more of the configurations of the laminating apparatus 10 of FIG. 1 and the operating principles of the laminating apparatus 10 will be described in more detail.

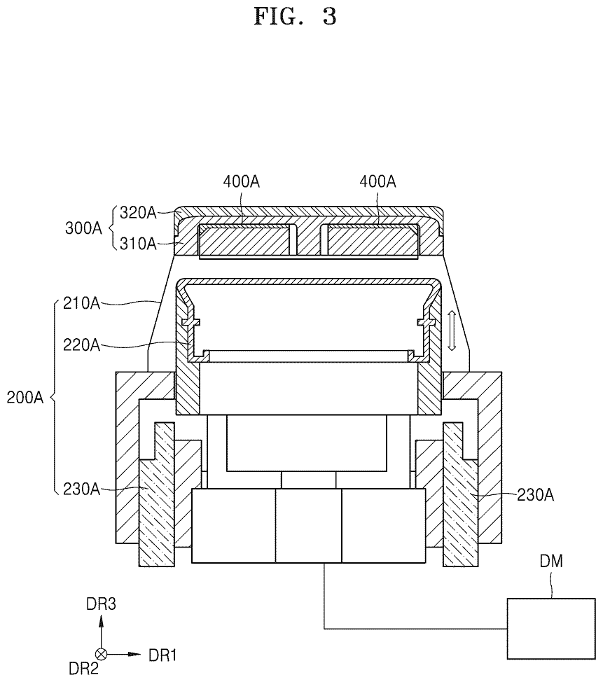

FIG. 3 is a view illustrating an example of one or more components of the laminating apparatus of FIG. 1. The illustration of FIG. 3 will focus on a second jig 200A of the laminating apparatus and components arranged on the second jig 200A.

FIG. 3 illustrates one or more embodiments in which the second jig 200A is connected to the driver DM and provided to be movable up and down, and the following description will focus on these features. In one or more embodiments, a first jig arranged opposite to the second jig 200A of FIG. 3 may be fixedly arranged or may be connected to the driver DM to be moved up and down.

Referring to FIG. 3, the second jig 200A may include a housing 210A, a lifting pad 220A, and lifting guides 230A. The second jig 200A may be connected to a driver DM to be moved linearly.

The housing 210A may form the contour of the second jig 200A. The housing 210A may be provided with the lifting pad 220A and the lifting guide 230A in the housing 210A. Furthermore, a pressing pad 300A may be arranged such that a pad core 310A is coupled to one side of the housing 210A and a pad cover 320A covers the pad core 310A.

The lifting pad 220A may be arranged in the housing 210A. The lifting pad 220A may be arranged in the housing 210A but may be to support at least an area of the pressing pad 300A. The lifting pad 220A may be coupled to the driver DM to be deformed and may be capable of linearly moving the pressing pad 300A.

In one or more embodiments, the lifting pad 220A may be connected to the driver DM to be supplied with air. If (e.g., when) air enters the lifting pad 220A, the lifting pad 220A may expand to push the pressing pad 300A upwards, and as a result, the pressing pad 300A may move in the third direction DR3, e.g., move upwards. In another example, If (e.g., when) air exits the lifting pad 220A, the lifting pad 220A may contract and the pressing pad 300 may move downwards.

The lifting guides 230A may be to guide deformation of the lifting pad 220A. If (e.g., when) the lifting pad 220A is deformed by an inflow or outflow of air, the lifting guides 230A may guide the lifting pad 220A to expand or contract in a single direction. As a result, the pressing pad 300A may be moved linearly.

Although FIG. 3 illustrates a pair of lifting guides 230A arranged on opposite sides of the lifting pad 220A, the placement and number of lifting guides 230A is not limited.

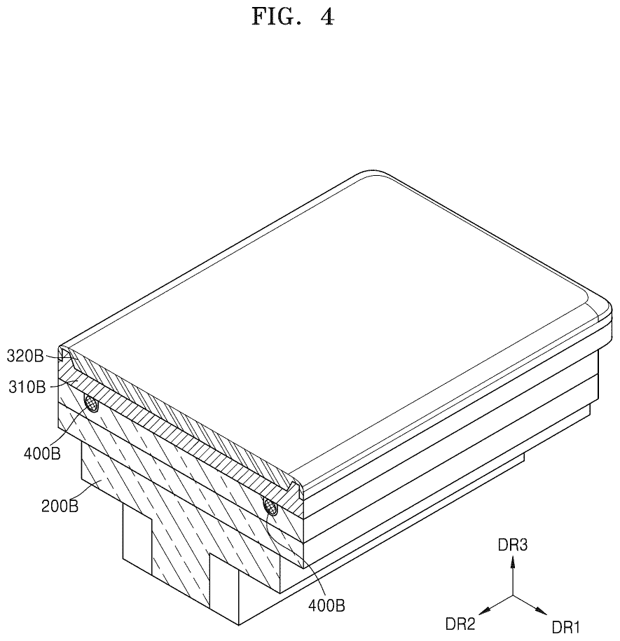

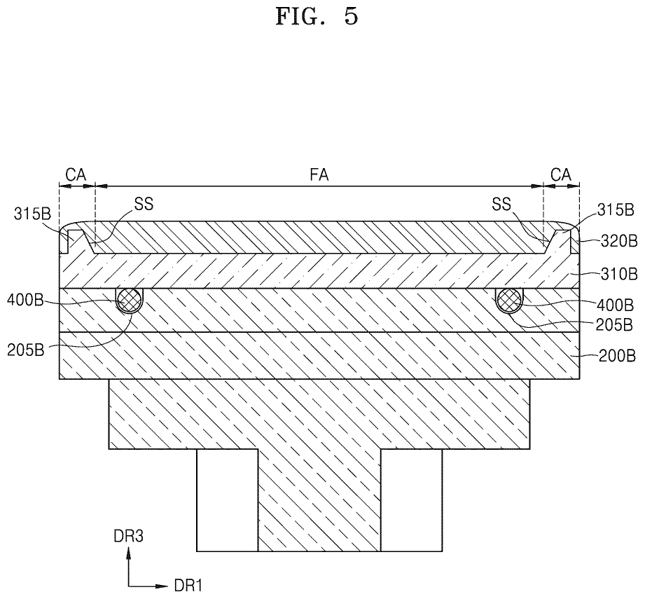

FIGS. 4 and 5 are views illustrating another example of one or more components of the laminating apparatus of FIG. 1. The illustration of FIGS. 4 and 5 will focus on a second jig 200B of the laminating apparatus and components arranged on the second jig 200B.

FIGS. 4 and 5 illustrate one or more embodiments in which the pressing pad 300B has a support structure, and the following description will focus on these features. Furthermore, FIG. 4 and FIG. 5 illustrate one or more embodiments in which the second jig 200B is fixedly arranged, and, in one or more embodiments, a first jig arranged opposite to the second jig 200B may be connected to the driver and provided to be movable up and down.

Referring to FIGS. 4 and 5, the pressing pad 300B may have support protrusions 315B on a pad core 310B.

The support protrusions 315B may be formed or arranged by protruding one side of the pad core 310B toward a pad cover 320B. Areas of the pad cover 320B corresponding to the support protrusions 315B may be recessed, allowing the pad cover 320B to be coupled to the pad core 310B.

As described in one or more embodiments, the pressing pad 300B may include a pad cover 320B arranged to act or serve as a buffer. The pad cover 320 may be formed or composed of a resilient material, and thus may change the shape in response to an external force applied to the panel member PM. At this time, the support protrusions 315B may be to support the pad cover 320B to minimize or reduce the deformation of the pad cover 320B. As a result, the pressing pad 300B may be to maintain the state substantially conforming to the shape of the cover window CW, and the panel member PM may be preformed and laminated.

In one or more embodiments, the support protrusions 315B may be arranged on areas corresponding to curved areas CA on the pad core 310B. As illustrated in FIGS. 4 and 5, the support protrusions 315B may be arranged on the respective curved areas CA of the pad core 310B. If (e.g., when) an external force is applied to the panel member PM, the curved areas CA of the pad cover 320B may also be subjected to the external force and be deformed outwards. Accordingly, the support protrusions 315B may be to more effectively or suitably maintain the shape of the pad cover 320B by intensively supporting the curved areas CA of the pad core 310B.

In one or more embodiments, the support protrusions 315B may have a support surface SS sloping toward the outside of the pad core 310B. The support surface SS may be to distribute stress caused by the pad cover 320B expanding outwards.

The laminating apparatus 10 may further include a heater. The heater may be to transfer heat to the panel member PM.

For example, in response to an external force being applied to the secondary film SF attached to the panel member PM, the secondary film SF and the panel member PM may be deformed together. At this time, a tensile force may be directly applied to the first area C1 of the panel member PM, but a compressive stress may be concentrated on the second area C2, thereby resulting in buckling.

The heater may be to transfer heat to the panel member PM to relieve the compressive stress concentrated on the panel member PM and reduce buckling. Furthermore, directly providing heat to the panel member PM, the secondary film SF attached to the panel member PM, and the adhesive layer bonding the panel member PM and the secondary film SF may reduce the time desired or required for the thermoplastic state change, thereby allowing the lamination process to be performed rapidly.

The heater may have heating elements 400A and 400B in contact with one or more areas of the pressing pad 300. The heating elements 400A and 400B may be to generate heat while in contact with the pressing pad 300.

The heating elements 400A and 400B may be arranged in at least one of the second jig 200 or the pressing pad 300. For example, the heating elements 400A may be arranged in the pad core 310 of the pressing pad 300, as illustrated in FIG. 3. In another example, as illustrated in FIGS. 4 and 5, the heating elements 400B may be inserted into a groove 205B of the second jig 200, and thus the heating elements 400B may be arranged between the pressing pad 300 and the second jig 200.

Each of the heating elements may be arranged in any suitable manner that is capable of generating or transferring heat. For example, the heating element may include a polyimide (PI) film and be arranged to generate heat. In another example, the heating element may be connected to an external power source and include a thermally conductive material to generate heat.

The heating elements 400A and 400B are not limited to a specific shape and may be formed or arranged in any suitable shape that is capable of contacting one or more area of the pressing pad 300 and transferring heat.

For example, the heating elements 400A may be provided in the shape of a plate having a selected (e.g., set or predetermined) cross-sectional area, as illustrated in FIG. 3. In another example, the heating elements 400B may have the shape of a line having a circular cross-section, as illustrated in FIGS. 4 and 5. In one or more embodiments, the heating elements 400B may be arranged in the “∩” shape to uniformly (e.g., substantially uniformly) transfer heat to the panel member PM while preventing damage (or reducing a degree or occurrence of damage) to the panel member PM as heat is transferred to an area where circuits and/or the like are concentrated.

Next, a laminating method for the panel member PM and the cover window CW utilizing the laminating apparatus according to one or more embodiments of the present disclosure 10 will be described in more detail.

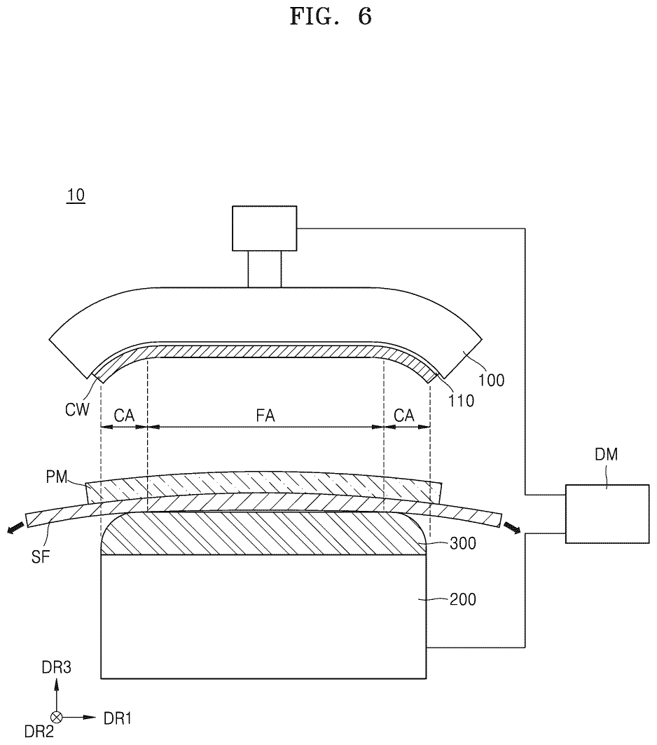

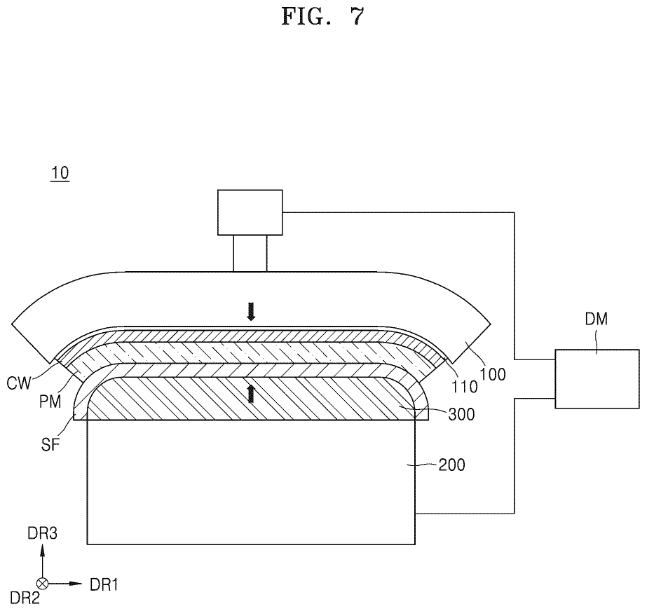

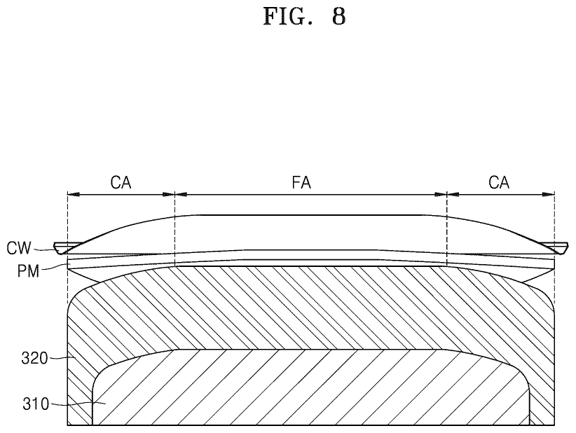

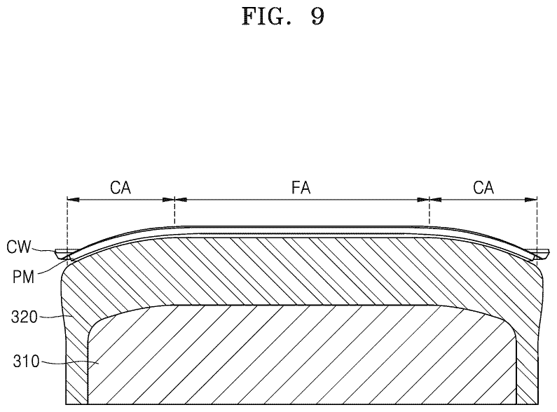

FIG. 6 is a conceptual view illustrating a state in which the laminating apparatus 10 of FIG. 1 preforms a panel member PM, and FIG. 7 is a conceptual view illustrating a state in which the laminating apparatus 10 of FIG. 1 laminates the panel member PM and a cover window CW. FIGS. 8 and 9 are cross-sectional views illustrating a process of deforming the panel member PM and the cover window CW. In FIGS. 8 and 9, the secondary film SF is not provided.

Referring to FIG. 1, FIG. 2, and FIG. 6 together, the laminating apparatus 10 may be to preform the panel member PM by applying a tensile force to the panel member PM.

The panel member PM may be seated on the pressing pad 300 arranged on the second jig 200 while attached to the secondary film SF. The film holder FP may be to apply a tensile force to the secondary film SF, and the tensile force may be transferred to the panel member PM. At this time, the panel member PM and the secondary film SF may be deformed while supported on the pressing pad 300. For example, in response to the bending of the panel member PM and the secondary film SF, the curved areas CA of the pressing pad 300 may contact a portion of the areas CA.

In this manner, the panel member PM may be subjected to and preformed by the tensile force applied to the secondary film SF while supported on the pressing pad 300. At this time, because the pressing pad 300 conforms to the shape of the cover window CW seated on the first jig 100, the tensile force may be distributed not only to the first area C1 of the panel member PM but also to the second area C2 of the panel member PM. Furthermore, the panel member PM may be deformed while supported on the pressing pad 300 to conform to the shape of the cover window CW.

Referring to FIGS. 7 to 9, the laminating apparatus 10 may be to press and laminate the panel member PM and the cover window CW.

At least one of the first jig 100 or the second jig 200 may be moved linearly by the driver DM. As the first jig 100 and the second jig 200 move closer, the cover window CW and the panel member PM may come into contact. Furthermore, the first jig 100 and the pressing pad 300 may be to apply pressure to the cover window CW and the panel member PM. As a result, the panel member PM may be deformed to conform to the shape of the cover window CW, and the cover window CW and the panel member PM may be laminated, thereby fabricating a display device.

For example, if (e.g., when) at least one of the first jig 100 or the second jig 200 moves linearly, the cover window CW may be placed adjacent to the panel member PM supported on the pressing pad 300, as illustrated in FIG. 8. In this state, if (e.g., when) the pressing pad 300 and the first jig 100 exert pressure on the cover window CW and the panel member PM, the cover window CW and the panel member PM may be attached.

As described in one or more embodiments, the pressing surface PS of the pressing pad 300 may have a flat area FA provided flat (e.g., substantially flat) in the central area to conform to the shape of the cover window CW and curved areas CA having a curvature at the opposite ends of the flat area FA. Therefore, the cover window CW and the panel member PM may be sequentially attached to each other from the central area to the curved areas CA at the periphery and finally completely (e.g., substantially completely) attached to each other as illustrated in FIG. 9. Accordingly, the laminating apparatus 10 may prevent air bubbles from being generated (or reduce a degree to or occurrence of which air bubbles are generated) between the panel member PM and the cover window CW, and fabricate a high-quality display device.

Furthermore, if (e.g., when) pressure is applied to the cover window CW and the panel member PM, the pad cover 320 formed or composed of a resilient material may reduce an impact applied to the panel member PM. Herein, as the force is distributed to the pad cover 320, the shape of the pad cover 320 may change, and, for example, the curved areas CA may expand outwards. Accordingly, because the pad cover 320 is formed or composed of a material having a selected (e.g., set or predetermined) or greater hardness, the pad cover 320 may effectively or suitably act or serve as a buffer while maintaining the shape conforming to the cover window CW as much as possible.

In another example, the panel member PM may be laminated after being preformed, as illustrated in FIG. 6 and FIG. 7, or the preforming (e.g., the preforming of the panel member) and the lamination (e.g., the laminating of the panel member and the cover window) may be performed at substantially the same time. For example, both (e.g., simultaneously) a tensile force and a compressive force may be applied to the panel member PM in a state where the first jig 100 and the second jig 200 are coupled, as illustrated in FIG. 7. Accordingly, the display device may be fabricated more rapidly and efficiently or suitably. For example, the panel member may undergo a preforming process prior to lamination, as illustrated in FIGS. 6 and 7. In one or more embodiments, the preforming of the panel member and its lamination to the cover window may occur concurrently. In such a case, both (e.g., simultaneously) tensile and compressive forces may be applied to the panel member while the first and second jigs are coupled, as illustrated in FIG. 7. This concurrent application of mechanical forces enables the panel to conform to the desired shape during lamination, thereby enhancing manufacturing efficiency and potentially reducing production time for the display device.

A laminating method utilizing the laminating apparatus according to one or more embodiments of the present disclosure may include the operations of: seating a cover window on a first jig; seating a panel member, to which a secondary film is attached, to a pressing pad arranged on a second jig; preforming the panel member by applying a tensile force to the secondary film; and laminating the preformed panel member and the cover window.

For example, a cover window CW having a curvature in at least an area may be seated on the seating surface AS of the first jig 100. The panel member PM attached to the secondary film SF may be seated on the pressing pad 300 arranged on the second jig 200. At this time, at least one side of the secondary film SF may be gripped by the film holder FP.

The secondary film SF may be tensioned by the film holder FP while supported on the pressing pad 300. At this time, the panel member PM may be subjected to the tensile force applied to the secondary film SF to be deformed and preformed together with the secondary film SF.

In the panel member PM, the first area C1 connected to the secondary film SF may be directly subjected to the tensile force, and the tensile force may also be distributed to the second area C2 not connected to the secondary film SF in a state where the panel member PM is supported on the pressing pad 300. As a result, the panel member PM may be deformed under the tensile force to contact a portion of the curved areas CA of the pressing pad 300.

At least one of the first jig 100 or the second jig 200 may be to move linearly, such that the panel member PM and the cover window CW may be arranged adjacent to each other. In response to the linear movement of at least one of the first jig 100 or the second jig 200, the first jig 100 and the pressing pad 300 may be to press the panel member PM and the cover window CW to be attached.

In one or more embodiments, because the pressing pad 300 is curved to conform to the shape of the cover window CW, the panel member PM may be deformed to conform to the shape of the cover window CW and bonded to the cover window CW while supported on the pressing pad 300. As a result, a display device in which the panel member PM and the cover window CW are laminated may be fabricated.

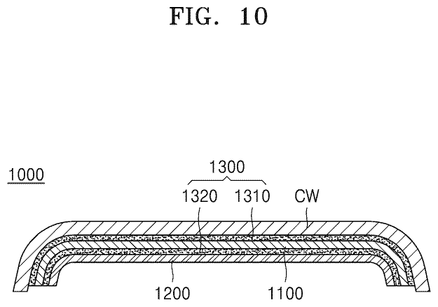

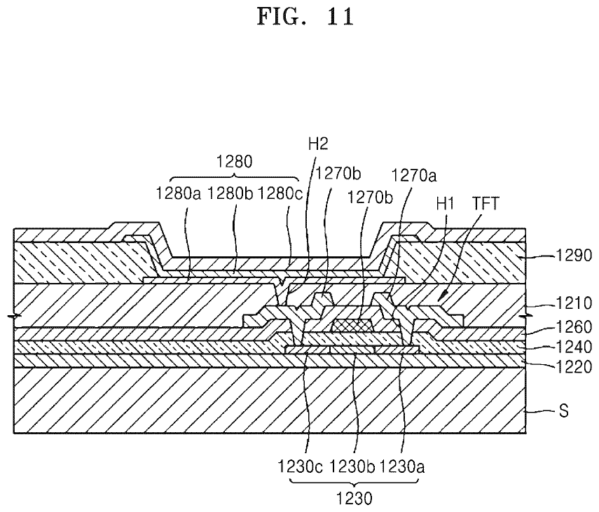

FIG. 10 is a conceptual view illustrating a display device 1000 fabricated by the laminating apparatus 10 of FIG. 1, and FIG. 11 is a cross-sectional view illustrating portions of a display panel 1200 as illustrated in FIG. 10.

Referring to FIGS. 10 and 11, the display device 1000 may have a cover window CW, a touch panel 1100, and the display panel 1200. The touch panel 1100, the display panel 1200, or a (e.g., any suitable) combination thereof may be provided as the panel member PM as described in one or more embodiments to be laminated to the cover window CW by the laminating apparatus.

For example, the panel member PM arranged on the laminating apparatus 10 may include at least one of the touch panel 1100 or the display panel 1200. The panel member PM may include only the touch panel 1100 and be attached to the cover window CW. In another example, the panel member PM may include only the display panel 1200 and be attached to the cover window CW. For example, the panel member PM may include both (e.g., simultaneously) the touch panel 1100 and the display panel 1200 and be attached to the cover window CW.

The panel member PM may include an adhesive layer 1300 arranged between at least two of the cover window CW, the touch panel 1100, or the display panel 1200. Herein, the adhesive layer arranged between the touch panel 1100 and the cover window CW may be defined as a first adhesive layer 1310, and the adhesive layer arranged between the touch panel 1100 and the display panel 1200 may be defined as a second adhesive layer 1320.

The first adhesive layer 1310 and the second adhesive layer 1320 may be formed or arranged in one or more suitable shapes. For example, each of the first adhesive layer 1310 and the second adhesive layer 1320 may include an adhesive film (e.g., an optical clear adhesive (OCA) film) and/or an adhesive material.

The first adhesive layer 1310 may be formed or arranged to match the size of the touch panel 1100. Furthermore, the second adhesive layer 1320 may be formed or arranged to match the size of the display panel 1200.

For ease of explanation, the following description will focus on a case in which the panel member includes the first adhesive layer 1310, the touch panel 1100, the second adhesive layer 1320, and the display panel 1200.

The display panel 1200 may include a first substrate S and a light-emitting element. For example, the display panel 1200 may include an encapsulation provided over the light emitting portion. In one or more embodiments, the encapsulation may be in the shape of a thin film encapsulation. Furthermore, the encapsulation may include a second substrate in addition to being in the shape of a thin film encapsulation. However, for ease of explanation, the following description will focus on the case in which the encapsulation is in the shape of a thin film.

The light-emitting element may be provided over the first substrate S. The light-emitting element may be provided with a thin-film transistor TFT, a passivation film 1210 may be provided to cover the thin-film transistor TFT, and an organic light-emitting element 1280 may be provided on the passivation film 1210.

In one or more embodiments, the first substrate S may be formed or composed of, but is not necessarily limited to, glass, and may be formed or composed of a plastic and/or a metal, such as SUS (Stainless Steel) and/or Ti. Furthermore, the first substrate S may be formed or composed of polyimide (PI). For ease of explanation, the following will focus in more detail on a case in which the first substrate S is formed or composed of polyimide.

A buffer layer 1220 including an organic compound and/or an inorganic compound may further be provided on the top surface of the first substrate S, and the organic compound and the inorganic compound may be formed or composed of silicon oxide (e.g., SiOₓ, wherein 0<x≤2; e.g., SiO₂) and silicon nitride (e.g., Si₃N₄ or SiNₓ, wherein 0<x≤2), respectively.

An active layer 1230 arranged in a selected (e.g., set or predetermined) pattern may be formed or arranged on the buffer layer 1220 and then embedded with a gate insulating layer 1240. The active layer 1230 may have a source region 1230a and a drain region 1230c and may further include a channel region 1230b between the source region 1230a and the drain region 1230c.

The active layer 1230 may be formed or arranged by forming or arranging an amorphous (e.g., non-crystalline) silicon film on the buffer layer 1220, crystallizing the amorphous (e.g., non-crystalline) silicon film into a polycrystalline silicon film, and patterning the polycrystalline silicon film. In the active layer 1230, the source and drain regions 1230a and 1230c may be doped with impurities depending on the type (kind) of thin-film transistors (TFTs), such as a driving TFT, a switching TFT, and/or the like.

A gate electrode 1250 corresponding to the active layer 1230 and an interlayer insulating layer 1260 embedding the gate electrode 1250 may be provided on the top surface of the gate insulating layer 1240.

Furthermore, after contact holes are formed or arranged in the interlayer insulating layer 1260 and the gate insulating layer 1240, a source electrode 1270a and a drain electrode 1270b may be formed or arranged on the interlayer insulating layer 1260 to contact the source region 1230a and the drain region 1230c, respectively.

The passivation film 1210 may be formed or arranged on the thin-film transistor formed or arranged as described in one or more embodiments, and a pixel electrode 1280a of an organic-light emitting element (OLEF) may be provided on the passivation film 1210. The pixel electrode 1280a may contact the drain electrode 1270b of the TFT through a via-hole H2 formed or arranged in the passivation film 1210. The passivation film 1210 may be a single layer or two or more layers formed or composed of an inorganic material and/or an organic material and may be formed or arranged as a planarization film such that the top surface is flat (e.g., substantially flat) regardless of the curvature of the underlying film or formed or arranged to be curved along the curvature of the underlying film. Furthermore, the passivation film 1210 may be formed or composed of a transparent (e.g., substantially transparent) insulator (e.g., electrical insulator) to achieve a resonance effect.

After the pixel electrode 1280a is formed or arranged on the passivation film 1210, a pixel defining film 1290 may be formed or composed of an inorganic material and/or an organic material to cover the pixel electrode 1280a and the passivation film 1210 and may be opened to expose the pixel electrode 1280a.

Furthermore, an organic light-emitting layer 1280b and a counter electrode 1280c may be formed or arranged on at least the pixel electrode 1280a.

The pixel electrode 1280a may be to function as an anode electrode, and the counter electrode 1280c may be to function as a cathode electrode, but the polarity of the pixel electrode 1280a and the polarity of the counter electrode 1280c may be reversed.

The pixel electrode 1280a may be formed or composed of a high work function material, e.g., a transparent (e.g., substantially transparent) conductor (e.g., electrical conductor), such as indium tin oxide (ITO), indium zinc oxide (IZO), indium oxide (In₂O₃), zinc oxide (e.g., ZnOₓ, wherein 0<x≤2; e.g., ZnO), and/or the like.

The counter electrode 1280c may be formed or composed of a metallic material, such as silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and any suitable compounds thereof having a low work function and may be formed or arranged into a thin semi-transparent reflective film of Mg, Ag, Al, and/or the like to transmit light after optical resonance.

The organic light-emitting layer 1280b may be implemented as a low molecular weight organic film (e.g., an organic film made of low molecular weight compounds) or a high molecular weight organic film (e.g., an organic film made of high molecular weight compounds). If (e.g., when) a low molecular weight organic film is utilized, a hole injection layer (HIL), a hole transport layer (HTL), an emission layer (EML), an electron transport layer (ETL), an electron injection layer (EIL), and/or the like may be stacked in a single structure or a composite structure, and one or more suitable organic materials including copper phthalocyanine (CuPc), N,N-di(naphthalene-1-yl)-N, N′-diphenyl-benzidine (NPB), tris-8-hydroxyquinoline aluminum (Alq3), and/or the like may also be used. The low molecular weight organic films may be formed or arranged by vacuum deposition. At this time, the hole injection layer, the hole transport layer, the electron transport layer, the electron injection layer, and/or the like may be common layers and may be applied to red, green, and blue pixels in common. Therefore, in contrast to FIG. 11, the common layers may be formed or arranged to cover the entire pixels, such as the counter electrode 1280c.

In the case of a high molecular weight organic film, a structure including a hole transport layer (HTL) and an emission layer (EML) may be generally utilized, in which poly(3,4-ethylenedioxythiophene) (PEDOT) is used for the hole transport layer and a high molecular weight organic material, such as polyphenylene vinylene (PPV) and/or polyfluorene (PFN), is used for the electroluminescent layer, and the hole transport layer and the electroluminescent layer may be formed or arranged by screen printing, ink jet printing, and/or the like.

It should be appreciated that the organic layer as described in one or more embodiments is not necessarily limited to the embodiments as described herein and that one or more suitable embodiments may be applied.

In one or more embodiments, the encapsulation may be formed or arranged as a thin-film encapsulation as described in one or more embodiments. For example, the encapsulation may be formed or arranged by alternately stacking one or more organic layers and one or more inorganic layers. For example, the inorganic layer or the organic layer may each be a plurality of layers.

The organic layer may be formed or composed of a polymer and may be a single film or a laminated film formed or composed of one selected from among polyethylene terephthalate, polyimide, polycarbonate, epoxy, polyethylene, and polyacrylate. For example, the organic layer may be formed or composed of polyacrylate, and, for example, may include a polymerized monomer composition including a diacrylate-based monomer and/or a triacrylate-based monomer. The monomer composition may further include a monoacrylate-based monomer. The monomer composition may further include, but is not limited to, a photoinitiator, that is generally available or generally used, such as diphenyl(2,4,6-trimethylbenzoyl)-phosphine oxide (TPO).

The inorganic layer may be a single film or a laminated film including a metal oxide and/or a metal nitride. For example, the inorganic layer may include any one of SiNₓ (wherein 0<x≤2), Al₂O₃, SiO₂, TiO₂, or TiO₂.

The top layer of the encapsulation exposed to the outside may be formed or arranged as an inorganic layer to prevent moisture permeation (or reduce a degree or occurrence of moisture permeation) to the organic light-emitting element.

The encapsulation may include at least one sandwich structure in which at least one organic layer is provided between at least two inorganic layers. Furthermore, the encapsulation may include at least one sandwich structure in which at least one inorganic layer is provided between at least two organic layers.

The encapsulation may include a first inorganic layer, a first organic layer, and a second inorganic layer sequentially from the top of the light-emitting element. The encapsulation may include a first inorganic layer, a first organic layer, a second inorganic layer, a second organic layer, and a third inorganic layer sequentially from the top of the light-emitting element. Furthermore, the encapsulation may include a first inorganic layer, a first organic layer, a second inorganic layer, a second organic layer, a third inorganic layer, a third organic layer, and a fourth inorganic layer sequentially from the top of the light-emitting element.

A metal halide layer including LiF may further be included between the light-emitting element and the first inorganic layer. The metal halide layer may prevent the light-emitting element from being damaged (or reduce a degree to or occurrence of which the light-emitting element is damaged) during formation or arrangement of the first inorganic layer by a sputtering method and/or a plasma deposition method.

The first organic layer may have a smaller area than the second inorganic layer, and the second organic layer may also have a smaller area than the third inorganic layer. Furthermore, the first organic layer may be completely (e.g., substantially completely) covered with the second inorganic layer, and the second organic layer may also be completely (e.g., substantially completely) covered with the third inorganic layer.

The encapsulation may include a second substrate as described in one or more embodiments. In one or more embodiments, the second substrate may be formed or arranged similarly to the first substrate S. For example, the second substrate may be formed or composed of a material similar to the first substrate S, such as, but not necessarily limited to, a glass material, and may also be formed or composed of a plastic material.

The touch panel 1100 may be provided in the shape of a panel and arranged on the display panel 1200 and may be provided in the shape of a pattern and arranged on the display panel 1200. For example, the touch panel 1100 may be provided on the encapsulation. Furthermore, the touch panel 1100 may be provided in the shape of a panel or in the shape of a pattern on the cover window CW as described in one or more embodiments.

The formation or arrangement of the touch panel 1100 may be generally available or generally used in the art, and therefore may not be described herein in more detail. Furthermore, for ease of explanation, the following description will focus on a case in which the touch panel 1100 is provided as a panel attached to the display panel 1200.

Hereinafter, a method of fabricating the display device 1000 as described in one or more embodiments will be described in more detail.

The cover window CW may be machined to fabricate the display device 1000. In one or more embodiments, the cover window CW may include one or more suitable types (kinds) of materials. For example, the cover window CW may be formed or composed of glass and/or plastic. For example, the cover window CW is not limited to the embodiments as described herein and may include any suitable material, a portion of which may be curved.

During the machining of the cover window CW as described in one or more embodiments, the opposite ends of the cover window CW may be curved by bending. At this time, the curved opposite ends of the cover window CW may be formed or arranged to be curved from the flat (e.g., substantially flat) portion of the cover window CW. For example, the curved portions of the cover window CW may be formed or arranged by extending from the flat (e.g., substantially flat) portion of the cover window CW as described in one or more embodiments and may be formed or arranged in the shape of an arc of a selected (e.g., set or predetermined) radius. In one or more embodiments, the curved portions of the cover window CW may be formed or arranged in an elliptical shape (e.g., a substantially elliptical shape) instead of an arc shape (e.g., a substantially arc shape).

As described in one or more embodiments, the touch panel 1100 and the display panel 1200 may be fabricated during or upon completion of the manufacturing of the cover window CW. At this time, the method of fabricating the touch panel 1100 and the display panel 1200 may be substantially the same as the fabricating method that is generally available or generally used, and therefore may not be described herein in more detail.

Once the preparation of the touch panel 1100 and the display panel 1200 is complete, the second adhesive layer 1320 may be deposited or arranged on one side of the display panel 1200. For example, the second adhesive layer 1320 may be deposited or arranged on the encapsulation.

The second adhesive layer 1320 may be formed or arranged in the shape of a film and attached to the encapsulation or may be formed or arranged in the shape of a material and applied to the encapsulation. However, for ease of explanation, the following description will focus on a case in which the second adhesive layer 1320 is formed or arranged in the shape of a film.

After the process as described in one or more embodiments is completed, the touch panel 1100 and the display panel 1200 may be attached to each other. At this time, the method of attaching the touch panel 1100 and the display panel 1200 to each other may be substantially the same as the method that is generally available or generally used, and therefore may not be described herein in more detail.

After the attachment of the touch panel 1100 and the display panel 1200 is completed as described in one or more embodiments, the first adhesive layer 1310 may be applied to the touch panel 1100. At this time, the method of applying the first adhesive layer 1310 may be substantially the same as or similar to the method of applying the second adhesive layer 1320, and therefore may not be described herein in more detail.

During or upon completion of the process as described in one or more embodiments, the panel member PM may be seated on the secondary film SF. At this time, an adhesive and/or the like may be applied to the secondary film SF to fix the panel member PM.

The cover window CW may be seated on the first jig 100 of the laminating apparatus 10. At this time, the cover window CW may be fixed by the window holder 110 of the first jig 100. The seating surface AS of the first jig 100 may be formed or arranged to conform to the shape of the cover window CW to fully contact one surface of the cover window CW. Furthermore, the seating surface AS of the first jig 100 may be formed or arranged to be recessed at one side of the first jig 100.

The panel member PM attached to the secondary film SF may be seated on the pressing pad 300 arranged on the second jig 200 of the laminating apparatus 10. The secondary film SF may be fixed to the film holder FP of the laminating apparatus 10. At this time, the film holder FP may pull the opposite ends of the secondary film SF, thereby preventing the central portion of the secondary film SF from sagging due to the load (or reducing a degree to or occurrence of which the central portion of the secondary film SF sags due to the load).

If (e.g., when) the panel member PM and the cover window CW attached to the secondary film SF are seated on the laminating apparatus 10 as described in one or more embodiments, the laminating apparatus 10 may be operated to linearly move at least one selected from the first jig 100 and the second jig 200.

In response to the movement of the first jig 100 and/or the second jig 200, the first adhesive layer 1310 may contact the cover window CW. The first adhesive layer 1310 may be compressed by contact with the cover window CW, and, for example, because the central area of the second jig 200 protrudes relatively toward the first jig 100, the central portion of the first adhesive layer 1310 may first contact the cover window CW. For example, in response to the movement of the first jig 100 and the second jig 200, attaching the cover window CW and the first adhesive layer 1310 to each other may be performed sequentially from the central portion to the opposite ends.

During the process as described in one or more embodiments, the film holder FP may be to move together with the first jig 100 or may be fixed.

As described in one or more embodiments, the laminating apparatus 10 may be to press the cover window CW and the panel member PM into contact in response to the movement of at least one of the first jig 100 or the second jig 200. At this time, the pressing pad 300 of the laminating apparatus 10 may be to distribute and equalize a pressure or force applied to the cover window CW and the panel member PM.

Upon completion of the process as described in one or more embodiments, the display device 1000 may be fabricated. At this time, the display device 1000 may be in a state of being attached to the secondary film SF and may be seated on the first jig 100 together with the cover window CW. The user may separate the secondary film SF from the film holder and then separate the display device 1000 from the secondary film SF. Thereafter, the user may take out the display device 1000 from the laminating apparatus 10.

The process as described in one or more embodiments may be performed in a vacuum. In one or more embodiments, the laminating apparatus 10 may include a chamber and a pressure regulator arranged in the chamber to regulate the internal pressure of the chamber. For example, the pressure regulator may include a suction pipe connected to the chamber and a vacuum pump arranged in the suction pipe.

As described in one or more embodiments, the laminating apparatus 10 may laminate the panel member PM and the cover window CW to rapidly and accurately or suitably fabricate the display device 1000. For example, the laminating apparatus 10 may minimize or reduce the defect rate and improve or enhance the quality of the product by accurately or suitably attaching the curved cover window CW and the panel member PM. Furthermore, the laminating apparatus 10 may effectively or suitably evacuate air bubbles generated between the cover window CW and the panel member PM during the lamination process, thereby firmly or suitably bonding the cover window CW and the panel member PM.

The laminating apparatus according to one or more embodiments of the present disclosure and the laminating method utilizing the laminating apparatus may press and laminate a panel member and a cover window. The panel member may be subjected to a tensile force and a compressive force while supported on the pressing pad, thereby changing the shape. In one or more embodiments, the pressing pad may have the pressing surface conforming to the shape of the cover window, which may prevent quality deterioration (or reduce a degree or occurrence of quality deterioration), such as buckling due to an external force applied to the panel member, and allow the panel member and the cover window to be attached to each other in full contact.

The laminating apparatus and the laminating method utilizing the laminating apparatus according to one or more embodiments of the present disclosure may effectively or suitably attach a cover window, a portion of which is formed or arranged as a curved surface, and a panel member to each other, thereby achieving product quality and improving or enhancing mass production and reliability. Furthermore, the laminating apparatus and the laminating method according to one or more embodiments of the present disclosure may accurately or suitably and rapidly fabricate display devices, thereby reducing work time and reducing fabrication costs.

The respective embodiments as described in one or more embodiments are embodiments that may be practiced independently, the respective structures of the embodiments may be used in combination with other embodiments.

While the subject matter of the present disclosure has been described in connection with what is presently considered to be practical example embodiments, it is to be understood that the present disclosure is not limited to the disclosed embodiments, but, in one or more embodiments, is intended to cover one or more suitable modifications and equivalent arrangements included within the spirit and scope of the appended claims and equivalents thereof. It therefore will be understood that one or more embodiments described herein are just illustrative but not limitative in all aspects.

In one or more embodiments, an electronic device may include: a controller to generate a scan input signal; a power device to generate a scan input voltage; and a display device including a display panel and a cover window covering the display panel.

In one or more embodiments, in the display device, the cover window may have a curvature in at least an area, and the display panel deformed to conform to a shape of the cover window may be bonded to the cover window.

A display device, an electronic device, an electronic apparatus, a device for manufacturing substantially the same and/or any other relevant devices or components according to one or more embodiments of the present disclosure may be implemented by utilizing any suitable hardware, firmware (e.g., an application-specific integrated circuit), software, or a (e.g., any suitable) combination of software, firmware, and hardware. For example, the one or more components of the device may be provided on one integrated circuit (IC) chip or on separate IC chips. Further, the one or more components of the device may be implemented on a flexible printed circuit film, a tape carrier package (TCP), and/or a printed circuit board (PCB), or provided on one substrate. Further, the one or more components of the device may be a process or thread, running on one or more processors, in one or more computing devices, executing computer program instructions and interacting with other system components for performing the one or more functionalities described herein. The computer program instructions may be stored in a memory which may be implemented in a computing device utilizing a standard memory device, such as, for example, a random access memory (RAM). The computer program instructions may also be stored in other non-transitory computer readable media, such as, for example, a CD-ROM, flash drive, and/or the like. Also, a person of skill in the art should recognize that the functionality of one or more computing devices may be combined or integrated into a single computing device, or the functionality of a particular computing device may be distributed across one or more other computing devices without departing from the scope of the present disclosure.

The certain implementations illustrated and described in the embodiments are examples and are not intended to limit the scope of the embodiments in any manner. Furthermore, a component may not be essential to the practice of the present disclosure unless the element is described as “essential” or “critical.”

The use of the term “the” and similar reference terms in the context of describing the embodiments are to be construed to cover both (e.g., simultaneously) the singular and the plural. Furthermore, the specification of a range herein includes embodiments in which individual values within the range are applied (unless otherwise indicated), as if (e.g., when) each individual value within the range were specified in the detailed description. Finally, the operations of the method according to one or more embodiments of the present disclosure may be performed in any appropriate or suitable order, unless the order of the operations is explicitly stated or otherwise. The present disclosure is not necessarily limited to the order in which the operations are described. The use of any examples or illustrative terms herein is only for the purpose of describing the embodiments in more detail, and the scope of the embodiments is not limited to the examples or illustrative terms unless defined by the appended claims. Furthermore, a person of ordinary knowledge in the art will appreciate that one or more suitable modifications, combinations, and alterations are possible depending on the design conditions and factors within the scope of the appended claims or equivalents thereof.

What is claimed is:

1. An apparatus comprising:
a first jig configured to support a cover window having a curvature in at least a portion thereof;
a second jig opposite to the first jig; and
a pressing pad on the second jig, the pressing pad being configured to support a panel member having a secondary film attached thereto and having a pressing surface conforming to a shape of the cover window,
wherein the apparatus is a laminating apparatus.

2. The apparatus as claimed in claim 1, wherein the pressing pad comprises:
a pad core coupled to the second jig; and
a pad cover covering the pad core and comprising a resilient material.

3. The apparatus as claimed in claim 2, wherein the pad cover has a hardness of a selected value or greater.

4. The apparatus as claimed in claim 2, wherein the pad core comprises a support protrusion protruding toward the pad cover.

5. The apparatus as claimed in claim 1, further comprising a heater comprising a heating element configured to generate heat while at least a portion of the heating element is in contact with the pressing pad.

6. The apparatus as claimed in claim 5, wherein the heating element is between the second jig and the pressing pad.

7. The apparatus as claimed in claim 5, wherein:
the pressing pad comprises a pad core to be coupled to the second jig, and
the heating element is in the pad core.

8. The apparatus as claimed in claim 1, further comprising a driver configured to linearly move at least one selected from among the first jig and the second jig,
wherein the second jig comprises:
a lifting pad connected to the driver and expandable to lift the pressing pad; and
a lifting guide configured to guide a direction of deformation of the lifting pad.

9. The apparatus as claimed in claim 1, further comprising a film holder adjacent to the second jig and configured to apply tension to the secondary film,
wherein the panel member is configured to receive a tensile force transmitted through the secondary film by the film holder, such that a portion of the panel member is deformed to conform to a curved portion of the pressing surface.

10. The apparatus as claimed in claim 1, wherein at least one of the first jig or the second jig is to move such that the panel member and the cover window contact each other, and the pressing pad is to press the panel member and the cover window.

11. A method comprising:
seating a cover window on a first jig;
seating a panel member, to which a secondary film is attached, on a pressing pad on a second jig;
preforming the panel member by applying a tensile force to the secondary film; and
pressing and laminating the panel member and the cover window,
wherein the method is a laminating method.

12. The method as claimed in claim 11, wherein the laminating of the panel member and the cover window comprises:
placing the panel member and the cover window adjacent to each other by moving at least one of the first jig or the second jig; and
attaching the panel member and the cover window to each other by pressing the panel member and the cover window.

13. The method as claimed in claim 11, wherein:
the cover window has a curvature in at least an area, and
the pressing pad is to support the panel member to which the secondary film is attached and has a pressing surface conforming to a shape of the cover window.

14. The method as claimed in claim 13, wherein, in the preforming of the panel member, the tensile force is applied to the panel member supported on the pressing pad such that the panel member is deformed to contact a curved portion of the pressing surface.

15. The method as claimed in claim 11, wherein, in the preforming of the panel member, when the tensile force is applied to the secondary film, the tensile force is transferred to a first area of the panel member, and the pressing pad is to support the panel member such that the tensile force is distributed to a second area adjacent to the first area.

16. The method as claimed in claim 11, wherein the laminating of the panel member and the cover window comprises pressing the panel member supported on the pressing pad to be deformed to conform to a shape of the cover window.

17. The method as claimed in claim 11, wherein:
the pressing pad comprises:
a pad core configured to be coupled to the second jig; and
a pad cover covering the pad core and comprising a resilient material, and
in the laminating of the panel member and the cover window, the pad cover is resiliently deformed to distribute pressure applied to the panel member.

18. The method as claimed in claim 11, further comprising generating heat and transferring the heat to the panel member by a heating element in contact with the pressing pad.

19. The method as claimed in claim 11, wherein the preforming of the panel member and the laminating of the panel member and the cover window are performed at substantially the same time.

20. An electronic device comprising:
a controller to generate a scan input signal;
a power device to generate a scan input voltage; and
a display device comprising a display panel and a cover window covering the display panel,
wherein in the display device, the cover window has a curvature in at least an area, and the display panel deformed to conform to a shape of the cover window is bonded to the cover window.
